(19) United States
(12) Patent Application Publication
(10) Pub. No.: US 2023/0027924 A1
(43) Pub. Date: Jan. 26, 2023

(54) METHOD OF MANUFACTURING A PLURALITY OF MECHANICAL RESONATORS IN A MANUFACTURING WAFER

(71) Applicant: Flexous Mechanisms IP B.V., Delft (NL)

(72) Inventors: Eola Jessica Giuffre, Delft (NL); Maarten Pieter Lustig, Delft (NL)

(73) Assignee: Flexous Mechanisms IP B.V., Delft (NL)

(21) Appl. No.: 17/813,169

(22) Filed: Jul. 18, 2022

(30) Foreign Application Priority Data
Jul. 20, 2021 (NL) 2028796

(51) Int. Cl. H03H 3/007; H03H 9/24; G04D 3/00

(52) U.S. Cl. CPC H03H 3/0077; H03H 9/2436; G04D 3/0035

(57) ABSTRACT

The invention relates to a method of manufacturing a plurality of mechanical resonators in a manufacturing wafer, the resonators being intended to equip a regulating member of a timepiece, the method comprising the following steps:
(a) fabricating a plurality of resonators in at least one wafer according to reference specifications;
(b) measuring the actual frequency of each of the plurality of resonators;
(c) determining the offset of the actual frequency of the resonators with respect to the reference specifications; and
(d) applying on at least one of the resonators at least two masses from a series of tuning masses to compensate the offset of the concerning resonator to bring the resonator closer to the reference specifications.

### FIELD OF THE INVENTION

The invention relates to a method of manufacturing a plurality of mechanical resonators in a manufacturing wafer, the resonators being intended to equip a regulating member of a timepiece, the method comprising the step of fabricating a plurality of resonators in at least one wafer according to reference specifications.

### BACKGROUND OF THE INVENTION

WO2021/053501 teaches such a method, wherein the step

a) fabricating of a plurality of resonators in at least one reference wafer according to reference specifications comprising at least one step of lithography to form patterns of the resonators on or above said reference wafer and a step of machining in said reference wafer through said patterns; is followed by the steps

(b) for the at least one reference plate, to establish a map indicative of the dispersion of stiffnesses of the resonators with respect to an average stiffness value;

(c) dividing the mapping into fields and determining a correction to be implemented to the dimensions of the resonators for at least one of said fields in order to reduce said dispersion;

(d) modifying the reference specifications for the lithography step to implement the dimensional corrections for said at least one field in the lithography step; and

(e) fabricate resonators on a build wafer using the modified specifications.

A problem with the method known from WO2021/053501 is that it is not possible to compensate each or practically each single resonator so that it will exhibit a frequency close to specification.

It is therefore an object of the invention to make it possible to compensate each single resonator or at least most resonators and bring it as close as possible to specification.

WO 2017/068538 discloses an oscillator for adjusting a mechanical timepiece movement, the oscillator comprising an escapement wheel and a resonator that forms the time base of the oscillator; the resonator including a mass element that is kept in oscillation by at least two vibrating elements; the mass element including at least one anchor portion that is rigidly connected to the mass element, and is configured so as to directly engage with the escapement wheel in order to maintain oscillations of the resonator. The oscillator is made from a single substrate, preferably a glass, ceramic, glass-ceramic or silicon substrate, the latter in the form of a wafer. The moment of inertia of the mass element can be modified by adding or removing weights on the mass element.

CH 709 291 relates to a rotating oscillator for a timepiece comprising a support element designed to allow the oscillator to be assembled on a timepiece, a balance, a plurality of flexible blades connecting the support element to the balance and able to exert a return torque on the balance, and a serge mounted integral with the balance.

EP 3 182 213 relates to a mechanism for adjusting an average speed in a timepiece movement comprises an escapement wheel and a mechanical oscillator, in which a plurality of blades, which are resiliently flexible in an oscillation plane, support and return a balance in such a way that this balance oscillates at an angle in the oscillation plane. A pallet fork comprises two rigid pallets which are rigidly connected to the balance and are arranged to co-operate alternately with a toothing of the escapement wheel when the balance oscillates at an angle.

US 2021/0026299 relates to a method including the following steps: a) providing a substrate including a first silicon layer, a second silicon layer and an intermediate silicon oxide layer therebetween; b) etching the first silicon layer in order to form the timepiece components therein; c) releasing from the substrate a wafer formed by at least all or part of the etched, first silicon layer and including the timepiece components; d) thermally oxidizing and then deoxidizing the timepiece components; e) forming by thermal oxidation or deposition a silicon oxide layer on the timepiece components; f) detaching the timepiece components from the wafer.

### SUMMARY OF THE INVENTION

According to the invention this object is achieved with the method according to one or more of the appended claims.

The invention is primarily embodied in a method wherein a plurality of mechanical resonators are manufactured in a manufacturing wafer, the resonators being intended to equip a regulating member of a timepiece, wherein the method comprises the following steps:

(a) fabricating a plurality of resonators in at least one wafer according to reference specifications;

(b) measuring the actual natural frequency of each of the plurality of resonators;

(c) determining the offset of the actual frequency of the resonators with respect to the resonator reference specifications; and

(d) applying on at least one of the resonators at least two masses from a series of tuning masses to compensate the offset of the concerning resonator so as to bring the resonator closer to the resonator reference specifications. This is most of the time sufficient to bring the resonators within specification.

It may be preferable that before applying step (d), the resonators are preferably removed from the wafer and sorted in groups (G1-G4), wherein the resonators in a particular group have a first offset from the reference specifications within a predefined first range, which first offset within the predefined first range differs from a second offset within a predefined second range of the resonators in another group, and so on for the other groups. Accordingly, this provides a coarse tuning step before the final tuning step. This is however not essential; the final tuning step can also be the one and only tuning step.

It is preferred to provide a wafer from silicon or a SOI wafer. This supports antimagnetic behaviour and provides high elasticity to keep hold on the tuning masses.

It is further preferable that before applying step (d), the resonators can be subjected to the step of oxidizing the resonators and/or depositing silicon oxide on the resonators followed by controlled removal of silicon oxide to provide at least some resonators and preferably all resonators with a silicon oxide layer thickness which brings at least some resonators and preferably all resonators closer to reference specifications.

It is preferred that before applying step (d) the individual groups are processed to a target frequency, preferably with a spread of 1 Hz or less. In an embodiment, the groups are processed by oxidizing the resonators and/or depositing silicon oxide on the resonators followed by controlled removal of silicon oxide to the target frequency.

According to the invention for each resonator that is compensated for symmetry reasons preferably two or a multiple of two masses are applied.

In certain embodiments it is preferable to apply at least two masses from a series of tuning masses, wherein each of the masses has a center of mass which is external of a geometric center of the mass, and that the masses that are applied to the resonator are rotated so as to finetune the resonator closer to its reference specifications.

With the method of the invention it is possible to provide that the series of tuning masses cover a range of the resonator of 10-15% of the reference specifications of the resonator.

It is preferable that adjacent masses in the series of tuning masses have different weights so as to enable tuning of the resonator with a frequency-step of 0.5% of the reference specifications of the resonator.

In one embodiment exactly two masses are applied for tuning the resonator closer to its reference specifications. As already mentioned above two masses are needed for symmetry (each mass applied on each mass of the resonator). If only one tuning mass would be used, this could create internal stress on the resonator with rising temperature and thus adversely affect the accuracy.

Suitably the masses have a tolerance of 10% with respect to design weight. This copes with manufacturing and assembly errors and ensures that the orientation error remains low.

It is further preferred that a tuning range of each mass overlaps between 0 and 50% with a tuning range of an adjacent mass in the series of tuning masses. This way manufacturing tolerances of the tuning masses can be easily dealt with.

It is further preferable that adding the tuning masses to the resonator increases the moment of inertia of the resonator in comparison with the same resonator without tuning masses by at least 1-100% or preferably by 1-30%. This is especially advantageous for lower frequency resonators or when one wants to use less groups of tuning masses. The frequency of the resonator can then be reduced without making use of thinner beams which will benefit the robustness of the resonator and reduces the chance for manufacturing errors.

One embodiment of the method of the invention is characterized by applying three masses on at least one of the resonators for tuning the resonator frequency and for tuning an orientation sensitivity of the resonator.

Another embodiment of the method of the invention is characterized by applying on at least one of the resonators three masses, wherein one mass of said three masses is applied to set the frequency of the resonator to a desired frequency, and two tuning masses of said three masses are applied to finetune the frequency of the resonator.

The invention will hereinafter be further elucidated with reference to exemplary embodiments of a method according to the invention that is not limiting as to the appended claims.

### BRIEF DESCRIPTION OF THE DRAWINGS

The following elucidation is made with reference to the drawings in which:

FIGS. 1A and 1B shows a wafer with resonators to be tuned with tuning masses according to the invention;

FIG. 2 shows grouped resonators with tuning masses;

FIG. 3 shows a resonator provided with two tuning masses; and

FIG. 4 shows a possible frequency spread covered by the tuning masses.

### DETAILED DESCRIPTION OF THE INVENTION

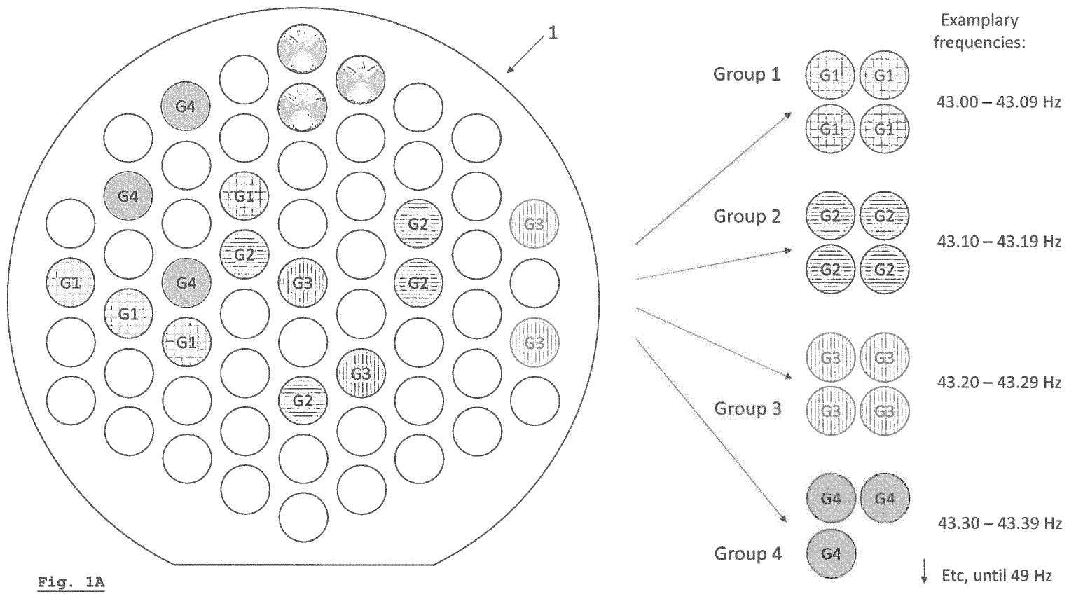

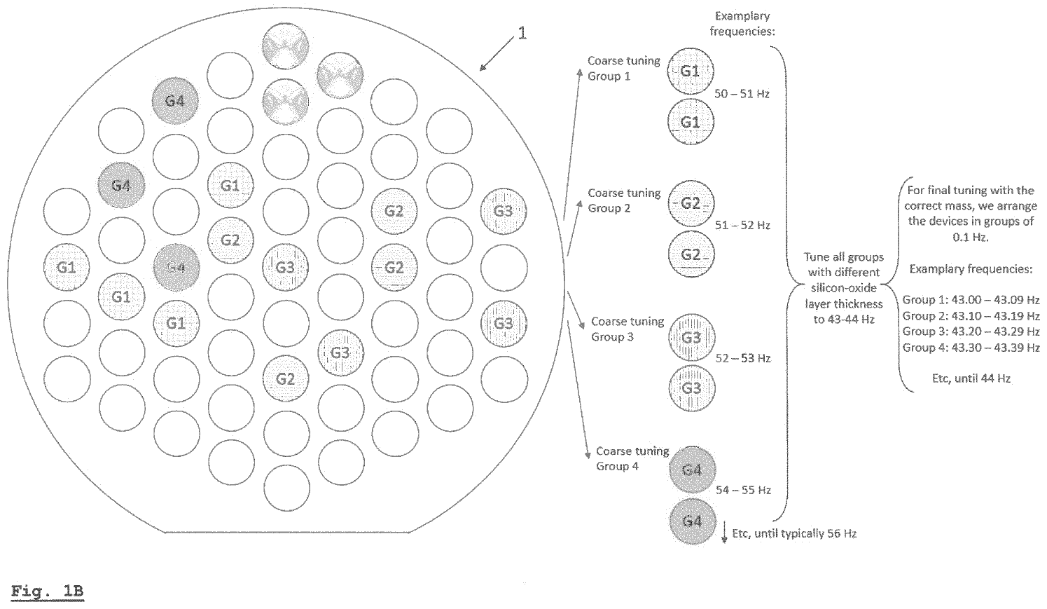

The resonators can for instance be manufactured in a lithography process or in any other suitable manufacturing method providing a wafer 1 with resonators. This is shown in FIG. 1A and FIG. 1B. The wafer 1 as is shown in FIGS. 1A and 1B is preferably from silicon or is a SOI wafer. It is clearly shown that when still in the wafer 1, the resonators G1-G4 are randomly distributed.

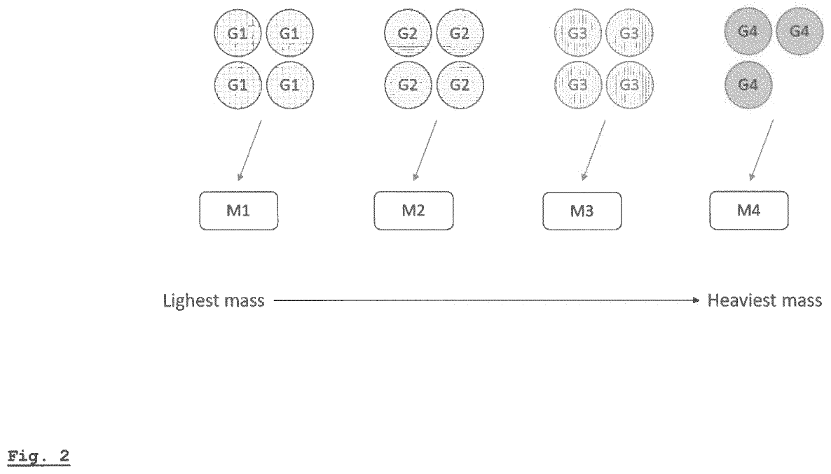

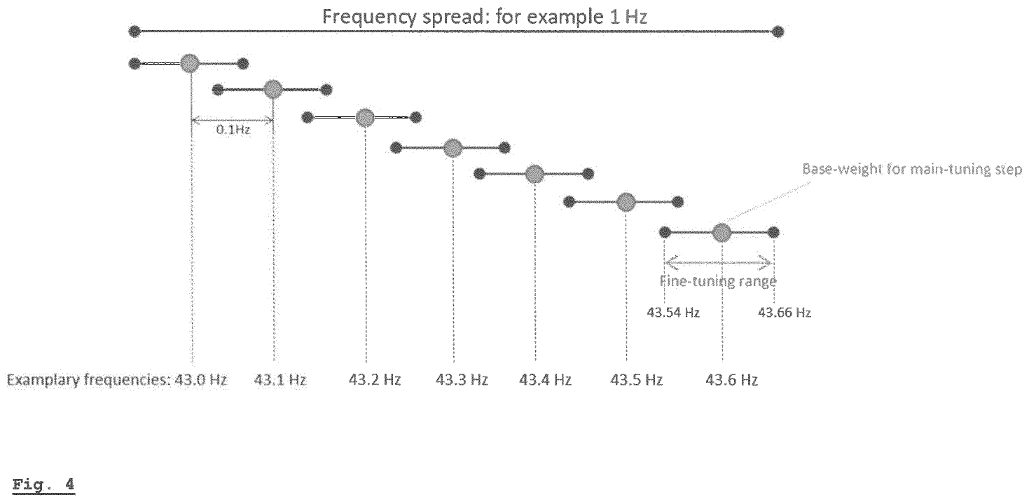

Two different methods of manufacturing are possible, the first method being more elaborate than the second method and including the following steps:
a. Manufacturing resonators in a wafer 1; the resulting resonators are distributed over a frequency range (e.g. having a spread of for instance ˜6 Hz), see FIG. 1B.
b. Taking all resonators from the wafer 1.
c. Measuring the natural frequency of each resonator.
d. Grouping the resonators with similar frequencies, e.g. in coarse tuning groups G1, G2, G3, G4 etc. of for instance ˜1 Hz (e.g. 50.0-51.0 Hz, 51.0-52.0 Hz, 53.0-54.0 Hz, and 54.0 Hz-55.0 Hz). This is shown on the right hand side in FIG. 1B.
e. Process the groups by oxidizing the resonators and/or depositing silicon oxide and removing silicon oxide to a target frequency with a spread of maximum for instance ˜1 Hz (resulting e.g. in a reduction of the total spread from 6 Hz to 1 Hz).
f. Pick the right masses for each oscillator (e.g. from a series of, e.g. 10, masses—M1, M2, M3, etc—of increasing weight, see FIG. 2) to compensate for the offset with the target resonating frequency according to specification. For reasons of accuracy, it is desirable that each tuning mass can tune a Δ of for instance 0.1 Hz. Desirably a series of 10 tuning masses is used which covers a 1 Hz spread around the target design frequency—this is shown in FIG. 4.

In a second, faster manufacturing method according to the invention, the following steps can be included:
a. Manufacturing resonators in a wafer 1; the resulting resonators are distributed over a frequency range (e.g. having a spread of for instance ˜6 Hz), see FIG. 1A.
b. Measuring all individual resonators while still part of the wafer 1.
c. Taking all resonators from the wafer 1; grouping the resonators with similar frequencies, e.g. in tuning groups G1, G2, G3, G4 etc.
d. Pick the right masses (from a series of 60 masses) for each resonator to compensate for the offset with the target design frequency according to specification; this is shown in FIG. 1A which relates to grouping the resonators G1-G4 with similar frequencies in fine tuning groups of for instance ˜0.1 Hz.

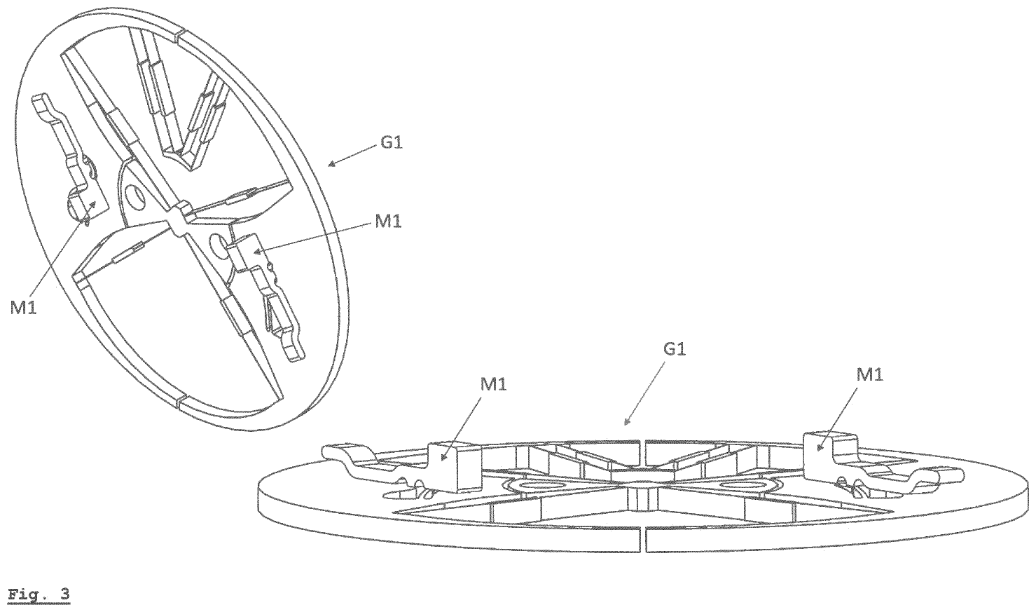

To summarize: both FIG. 1A and FIG. 1B depict the result of manufacturing a plurality of mechanical resonators G1-G4 in a manufacturing wafer 1, wherein the resonators G1-G4 are manufactured according to reference specifications, and wherein subsequently the steps are applied of
measuring the actual frequency of each of the plurality of resonators G1-G4; followed by
determining the offset of the actual frequency of the resonators G1-G4 with respect to the reference specifications; and
applying on (at least one of) the resonators G1-G4 at least two masses M1 (as shown in FIG. 3) from a series of tuning masses to compensate the offset of the concerning resonator G1-G4 so as to bring the resonator G1-G4 closer to the reference specifications.

It will be clear for the skilled person from FIG. 3 that each of the masses M1 has a center of mass which is external of a geometric center of the mass, and that the masses M1 that are applied to the resonator G1-G4 are rotated while applied on the resonator G1-G4 so as to finetune the resonator G1-G4 closer to its reference specifications.

Preferably the series of tuning masses M1, M2, M3, etc. as depicted in FIG. 2 cover a range of the resonator G1-G4 of max. 15% of the reference specifications of the resonator. Further it is desirable that adjacent masses M1, M2 or M2, M3, etc. in the series of tuning masses M1-M4 have different weights so as to enable tuning of each resonator G1-G4 with a frequency-step of 0.5% of the reference specifications of the resonator. With a design frequency for instance of 50 Hz, the tuning frequency range is preferably 2 Hz, and the frequency step will then be 0.2 Hz. Different values are however evidently feasible, as is shown in the exemplary embodiment of FIGS. 1A, 1B and 4.

With reference to FIG. 3 it is preferred that the at least two masses M1 have a mutual weight difference of less than 0.5%. Also, in this figure the embodiment is depicted in which exactly two masses M1 are applied for tuning the resonator G1 closer to its reference specifications. This can however also be a multiple of two masses M1.

Desirably the respective masses have a tolerance of 10% with respect to their design weight.

FIG. 4 depicts that a tuning range of each mass overlaps between 0 and 50% with a tuning range of an adjacent mass in the series of tuning masses. This is depicted by the centroid frequencies 43.0 Hz, 43.1 Hz, 43.2 Hz etc. The centroid frequency is in the middle of a tuning range, and neighbouring tuning ranges are clearly overlapping.

It is preferred that by adding the tuning masses to the resonator G1-G4 a moment of inertia of the resonator G1-G4 increases in comparison with the same resonator without tuning masses by 1-30%, or preferably by at least 1-100%.

Although the invention has been discussed in the foregoing with reference to exemplary embodiments of the method of the invention, the invention is not restricted to these particular embodiments which can be varied in many ways without departing from the invention. The discussed exemplary embodiments shall therefore not be used to construe the appended claims strictly in accordance therewith. On the contrary the embodiments are merely intended to explain the wording of the appended claims without intent to limit the claims to these exemplary embodiments. The scope of protection of the invention shall therefore be construed in accordance with the appended claims only, wherein a possible ambiguity in the wording of the claims shall be resolved using these exemplary embodiments.

It is for instance within the scope of the invention to apply three tuning masses on at least one of the resonators for tuning the resonator frequency and for tuning an orientation sensitivity of the resonator.

It is also within the scope of the invention to apply three masses on at least one of the resonators, wherein one mass of said three masses is applied to set the frequency of the resonator close to its reference specifications, and two masses of said three tuning masses are applied to finetune the frequency of the resonator even closer to the resonator's reference specifications.

1. A method of manufacturing a plurality of mechanical resonators in a manufacturing wafer, the resonators being intended to equip a regulating member of a timepiece, the method comprising steps of:
(a) fabricating a plurality of resonators in at least one wafer according to reference specifications;
(b) measuring an actual frequency of each of the plurality of resonators;
(c) determining an offset of the actual frequency of the resonators with respect to the reference specifications; and
(d) applying on at least one of the resonators at least two masses from a series of tuning masses to compensate for the offset of the concerned resonator to bring the resonator closer to the reference specifications.

2. The method according to claim 1, wherein before applying step (d) the resonators are sorted in groups and the resonators in a particular group have a first offset from the reference specifications within a predefined first range, which first offset within the predefined first range differs from a second offset within a predefined second range of the resonators in a second group.

3. The method according to claim 1, further comprising a step of providing a wafer (1) from silicon or a SOI wafer.

4. The method according to claim 1, wherein before applying step (d) the resonators are subjected to a step of controlled oxidizing of the resonators and/or a step of depositing silicon oxide on the resonators followed by controlled removal of silicon oxide to provide all resonators with a silicon oxide layer thickness which brings all resonators closer to reference specifications.

5. The method according to claim 1, wherein before applying step (d) the groups are processed to a target frequency.

6. The method according to claim 5, wherein the groups are processed by oxidizing the resonators and/or depositing silicon oxide on the resonators followed by controlled removal of silicon oxide to achieve the target frequency.

7. The method according to claim 1, wherein in step (d) each of the masses has a center of mass which is external of a geometric center of the mass, and that the masses that are applied to the at least one resonator are rotated so as to fine tune the at least one resonator closer to its reference specifications.

8. The method according to claim 1, wherein the series of tuning masses cover a range of the at least one resonator of a maximum of 15% of the reference specifications of the resonator.

9. The method according to claim 1, wherein adjacent masses in the series of tuning masses have different weights so as to enable tuning of the resonator with a frequency-step of 0.5% of the reference specifications of the resonator.

10. The method according to claim 1, wherein exactly two masses or a multiple of two masses are applied for tuning the resonator closer to its reference specifications.

11. The method according to claim 1, wherein the masses have a tolerance of 10% with respect to their design weight.

12. The method according to claim 1, wherein a tuning range of each mass overlaps between 0% and 50% with a tuning range of an adjacent mass in the series of tuning masses.

13. The method according to claim 1, wherein adding the tuning masses to the resonator increases a moment of inertia of the resonator in comparison with the same resonator without tuning masses by at least 1-100.

14. The method according to claim 1, wherein three masses are applied on at least one of the resonators for tuning the resonator frequency and an orientation sensitivity of the resonator.

15. The method according to claim 1, wherein three masses are applied to the at least one resonator, one of said three masses is applied to set the frequency of the resonator close to its reference specifications, and two masses of said three tuning masses are applied to fine tune the frequency of the resonator even closer to the resonator's reference specifications.

16. The method according to claim 5, wherein before applying step (d) the groups are processed to a target frequency with a spread of 1 Hz or less.

17. The method according to claim 1, wherein adding the tuning masses to the resonator increases a moment of inertia of the resonator in comparison with the same resonator without tuning masses by at least 1-30%.
